(19) United States
(12) Patent Application Publication
(10) Pub. No.: US 2024/0339551 A1
(43) Pub. Date: Oct. 10, 2024

(54) PHOTOVOLTAIC MODULE AND METHOD FOR MANUFACTURING THE SAME

(71) Applicant: MEYER BURGER (GERMANY) GMBH, Hohenstein-Ernstthal (DE)

(72) Inventors: Loris BARRAUD, La Chaux-de-Fonds (CH); Pierre PAPET, Hauterive (CH)

(21) Appl. No.: 18/580,499

(22) PCT Filed: Jun. 28, 2022
(86) PCT No.: PCT/EP2022/067807

§ 371 Date: Jan. 18, 2024

(30) Foreign Application Priority Data
Jul. 22, 2021 (EP) 21187247.8

(51) Int. Cl. H01L 31/05

(52) U.S. Cl. CPC H01L 31/0516

(57) ABSTRACT

An interdigitated back contact photovoltaic device includes a substrate having a structured layer with first and second doped structures. The substrate is divided, by a virtual axis in a first portion and a second portion. The first portion and second portion includes, arranged on the first-type structures and second type structures, electrical contacts that are aligned according to parallel first and second columns defining alternating negative and positive polarities. Each electrical contact of the columns of the first portion has a polarity opposite that of the electrical contacts of facing collinear columns of the second portion. The first and second portions include at least one non-rectangular corner. Also disclosed are resized photovoltaic devices that are the photovoltaic devices separated in two halves, and to modules that include the resized photovoltaic devices, as well as a method to realize the photovoltaic devices, the resized photovoltaic devices and the photovoltaic modules.

### CROSS-REFERENCE TO RELATED APPLICATIONS

This application is the US national stage of PCT/EP2022/067807, filed Jun. 28, 2022 and designating the United States, which claims the priority of EP 21187247.8, filed Jul. 22, 2021. The entire contents of each foregoing application are incorporated herein by reference.

### TECHNICAL FIELD

The present invention relates to the field of photovoltaic devices. More particularly, it relates to photovoltaic cells with back-contacts being of the interdigitated back contact (IBC) type in which the collecting material is patterned. The invention relates particularly to half-cut photovoltaic cells and photovoltaic modules comprising arrays of half-cut photovoltaic cells.

A particular advantageous application of the present invention is for the production of highly efficient photovoltaic modules, based on half-cut photovoltaic cells intended, for generating electrical energy but the invention also applies, more generally, to any similar device in which an incoming radiation is converted into an electrical signal.

### BACKGROUND OF THE INVENTION

One of the difficulties to make solar cell modules relying on Interdigitated back-contact (IBC) solar cells, such as tunnel junction IBC photovoltaic devices or other types of IBC cells, is related to the manipulation, orientation, and interconnect of the IBC solar cells in the manufacturing process of photovoltaic modules.

An IBC photovoltaic cell and module is described in for example the U.S. Pat. No. 9,419,153B1. The document describes solar modules realized by the alignment and interconnect of full-wafer IBC cells. FIG. 5 in U.S. Pat. No. 9,419,153B1 illustrates identical solar cell segments that are disposed 180° relative to each other in a solar cell module. Rows of contact openings of the solar cell segments are aligned with respect to each other such that the first rows of a first solar segment is aligned with the second row of a second adjacent solar segment. A vertical line of symmetry, defined in the length of the series of solar segments, extends centrally through the central column of the interconnected series of solar cell segments. Electrical lines are introduced in a framework, for the insertion and fixation of a multi-wire web. For example, FIG. 5 in U.S. Pat. No. 9,419,153B1 shows neighboring cells that are positioned with respect to each other with a rear-side contact structure in 180° rotation about their center so that subsequently a number of thin parallel wires of a multi-wire electrodes can be introduced on the cells and can be fixed on the surface. FIGS. 6,8 in U.S. Pat. No. 9,419,153B1 illustrate a framed section between two adjacent solar cells of a solar module.

In order to reduce power losses, due to the resistive power loss of full-wafer IBC cells, half-cut photovoltaic cells have been proposed that are full wafer-sized IBC cells that are cut in two halves. Gao et. al. presents an analysis of such modules in: Gao et al, “A quantitative analysis of photovoltaic modules using halved cells”, International Journal of photoenergy”, vol. 2013, article ID739374, pp 1-8, http://dx.doi.org/10.1155/2013/739374, August 2013.

Before realizing the modules, such half photovoltaic devices are stored in storage boxes before their individual manual or automatic handling, orienting and the stringing that includes interconnection of the half-cut PV cells onto a frame of a half-cut cell photovoltaic module.

The problem with the realization of half-cut photovoltaic cell modules, based on the selection and arrangement of half-sized photovoltaic cells, is that it requires the precise recognition of the order of the arrangement of the negative and positive electrical connections, while their outer shape are all identical. More precisely, in PV modules the positive pole conductors need to be aligned in line with the negative pole conductors of the adjacent and subsequent half-sized photovoltaic cell. This way of manufacturing of prior art half-cut cells for realizing modules is illustrated in FIG. 1.

For example, the photovoltaic cells that are described in the documents DE102008033189A1 and JP2014127552A are typical prior art cells that present the problem of having to recognize the order of the arrangement of the negative and positive electrical connections of half-cells, while their outer shape are all identical.

There are a number of problems related with such a manufacturing procedure. Not only the handling requires a rotation of 180 degrees of each subsequent selected half-photovoltaic device from its storage box or cartridge in an automated system, but there is also a risk of a wrong selection of a half-IBC cell. This may occur, for example, if at least two half-cut cells has been removed and be re-inserted in its storage box, which may occur accidently or during an inspection operation. In order to rearrange the half-cut cells back into the storage box, the manipulated half-cell has to be inspected to check the correct configuration of the polarity order of the array of conducting paths and rearranging them in the good order among the other half-cells, which is time consuming and prone to errors. The same risk exists in an automated system that is not capable to recognize the correct polarity arrangement, unless putting in place a very complicated and expensive handling system that may recognize the correct arrangement of the polarities in the lateral direction defined orthogonal to the conducting layers. Furthermore, in the case of a wrong selection of a half-cut cell the whole photovoltaic module may be destroyed if two subsequent half-cut cells have the wrong polarity arrangement relative to their neighboring half-cut cells.

There is thus a need for IBC cells that are designed differently so that the selection and handling of the half PV cells may be simplified and at the same time eliminate completely the risk of damage to PV modules due to wrong selection of half-curt cells and so a wrong wiring of the connections between the different adjacent half-IBC devices in these modules.

### SUMMARY OF THE INVENTION

The present invention relates to a photovoltaic device and to photovoltaic half-cells realized from photovoltaic device. The invention relates also to modules comprising a plurality of interconnected photovoltaic half-cells of the invention. The invention provides photovoltaic modules that have a different design and layout of the electrical contacts and that are easier to fabricate. The modules of the invention alleviate the problems of prior art modules based on half-cells of prior art. The modules of the invention are less expensive and less prone to possible electrical damages, as they rely on the use of identical half-cells of the invention, to the contrary of prior art modules based on half photovoltaic cells that rely on half-cells that have different polarity arrangements of the electrical contacts.

The interdigitated back contact (IBC) photovoltaic device 1 of the invention comprises:
a silicon-based substrate being of a p-type or n-type doping and having a first face defining a horizontal X-Y plane and a vertical direction Z orthogonal to said horizontal X-Y plane;
a patterned silicon layer comprising a plurality of first-type structures, being p-type or n-type doped structures, and a plurality of second-type structures being of the type opposite to said first-type, said first-type structures and second-type structures being of an alternating polarity type.

The silicon-based substrate, which comprises on top of it said patterned silicon layer, is divided in a first portion and a second portion. The intersection of the two portions defines a virtual separation axis X. The separation axis X comprises a device center C.

Said first portion comprises, arranged on said first-type and second-type structures, a plurality of electrical contacts aligned as a first series of parallel first columns that define alternating positive and negative polarities, said first columns being orthogonal to said virtual axis. The alternating polarities of the first columns are to collect alternatively, in operation of the device, holes and electrons provided by the contacted underlying doped structures. Said first portion comprises, to its side away from said virtual axis X, at least one corner that is not a rectangular corner. Such corner may have any shape.

Said second portion comprises, arranged on said second-type and first-type structures, a plurality of electrical contacts aligned as a second series of parallel second columns. The series of second columns define alternating negative and positive polarities and are arranged, similar to said first columns, orthogonal to said virtual axis. The alternating polarities of the contacts in second columns are arranged to collect alternatively, similar to the contacts of said first columns, holes and electrons provided by the contacted underlying doped structures. The second portion (2b) is identical to said first portion (2a) when virtually rotated, in said X-Y plane, by 180 degrees relative to said device center (C) as virtual rotation center.

Each of the electrical contacts of said first columns have, in the length Y orthogonal to said virtual axis X, a polarity opposite to the polarity of the electrical contacts of a facing second column.

Said second portion comprises, to its side away from said virtual axis X, at least one corner that is not a rectangular corner. The shape of this corner may be any shape.

In an embodiment, the number N of first columns and second columns are equal and/or is a pair number.

In an embodiment, the photovoltaic device comprises 4 corners that are non-rectangular corners. In an embodiment, at least 2 of the 4 corners are different shaped corners.

In an embodiment, said first columns and/or said second columns comprise an electrical connection layer connecting at least a part of the electrical contacts that are present in a column.

In an embodiment, said electrical contacts are realized in apertures realized in a deposited layer comprising a plurality of isolating portions arranged onto said first type and second type of said patterned silicon layer.

In an embodiment, said deposited layer is a fully insulating layer arranged onto said patterned silicon layer or a patterned conductive layer.

In an embodiment, the device comprises a gap that comprises said virtual X-axis and having a width TG being different than the separation distance S between identical electrical contacts in said first and second colons. The width TG and the separation distance S are defined in the Y-axis orthogonal to said virtual X-axis. Providing a dedicated gap may make the dicing or cutting operation between the two portions of the device 1 easier and require less precision.

The invention is also achieved by resized photovoltaic devices being said first portion or said second portion as obtained by the physical separation in two halves, along said virtual axis X, of the photovoltaic device as described

The invention is also achieved by a photovoltaic module comprising a plurality of adjacent resized photovoltaic devices that are arranged so that at least 80%, preferably at least 90% of said first columns of each first resized photovoltaic device is on a virtual line defined by a second column of an adjacent second resized photovoltaic device and so that facing collinear columns of adjacent half-cut cells have opposite polarities.

In an embodiment, the photovoltaic module comprises a plurality of adjacent resized photovoltaic devices that are arranged so that at least one of said first columns of each first resized photovoltaic device is not facing a second column of an adjacent second resized photovoltaic device.

The invention is also realized by a method for manufacturing a photovoltaic device comprising the steps of
providing a patterned silicon layer, comprising a plurality of first-type structures, being p-type or n-type doped structures, and a plurality of second-type structures, being of the type opposite to said first-type and defining two identical portions being a first portion and a second portion separated by a virtual separation axis X that includes a device center C, said first and second portion comprising, to their side away from said virtual axis, at least one corner that is not a rectangular corner;
realizing in said first portion, on said first-type structures and said second-type structures, a plurality of electrical contacts, arranged as a first series of parallel first columns of alternating positive and negative polarities in the direction of said virtual separation axis X;
realizing in said second portion, on said second-type structures and said first-type structures, a plurality of electrical contacts arranged as a second series of parallel second columns having alternating positive and negative polarities in the direction of said virtual separation axis X.

In the method, each of the electrical contacts of said first columns in said first portion have, in the length orthogonal to said virtual axis X, a polarity opposite to the polarity of the electrical contacts of a facing collinear second column in said second portion.

The invention is also achieved by a method for manufacturing of resized photovoltaic devices. The method comprises the steps of:
realizing a photovoltaic device as described;
separating the photovoltaic device as described by, along the virtual axis X, in two substantially identical resized photovoltaic devices.

In an embodiment, the plurality of resized photovoltaic devices are stored in a storage box.

The invention is also achieved by a method for manufacturing a photovoltaic module or string of solar cells comprising the step of assembling said resized photovoltaic devices so that columns of contacts are facing each other and so that columns that are substantially aligned in virtual lines, represented by said columns, have opposite polarities in an alternating way.

In an embodiment the connection columns of a first polarity of a resized photovoltaic device is performed with the columns of an adjoining resized photovoltaic device that have a second polarity, opposite to the first polarity, and so to realize an electrical series interconnection of the adjoining resized photovoltaic devices.

### BRIEF DESCRIPTION OF THE DRAWINGS

The present invention will now be described in reference to the enclosed drawings where:

FIG. 1 illustrates the realization of an IBC photovoltaic device according to a layout and method of prior art and another IBC photovoltaic device according to the invention.

FIG. 2 illustrates an IBC photovoltaic device of the invention comprising two photovoltaic portions that are each half-sized photovoltaic devices separated by a virtual axis that is orthogonal to the columns comprising electrical contacts. The virtual axis comprises a center of the IBC photovoltaic device and defines the flat border of each of the half-cut cells as illustrated in FIGS. 3-6, 8.

FIGS. 3 and 4 illustrate identical half-cut IBC photovoltaic device provided by the separation in two halves, along said virtual axis, of the photovoltaic device of FIG. 2.

FIG. 5 illustrate a half-cut IBC photovoltaic device which is the one illustrated in FIG. 4 that has been turned by 180° so that it may be stored like all the other half-cells provided by full photovoltaic devices as illustrated in FIG. 2.

FIG. 6 illustrates a series of half-cut cells, as illustrated in FIGS. 3-5, that are arranged in a box and with their flat side to the bottom of the box. When the two half-cut cells are positioned to present the same outer shape, as in a box or a charger of an automated machine, the columns of their conducting pads have all the same relative alternation of polarities, as defined relative to their flat sides which are the sides comprising two rectangular corners.

FIG. 7 illustrates the 2D arrangement of half-cut photovoltaic cells of prior art as required to make photovoltaic modules of prior art

FIG. 8 illustrates the 2D arrangement of half-cut photovoltaic cells to realize photovoltaic modules according to the invention. The half-cut cells are oriented so that their flat sides, defined as the sides comprising 2 tow rectangular corners, are facing and so that the virtual columns defined by their conducting pads have alternating polarities, i.e. a positive column of one half-cell is aligned with a negative column of the adjacent next half-cell.

FIG. 9 illustrates a typical substrate of photovoltaic device on which doped layers are provided. One of the doped layers are here a series of continuous parallel strips, over nearly the whole width of a substrate of doped layers (p or n) separated by areas that have an opposite doping i.e. n or p.

FIG. 10 illustrates photovoltaic device comprising the substrate of FIG. 4 and in which electrical contacts are provided to said doped layers.

FIG. 11 illustrates an embodiment of substrate of photovoltaic device on which doped layers are provided. One of the doped layers are here a matrix of parallel strips of doped layers (p or n) separated by areas that have an opposite doping i.e. n or p.

FIG. 12 illustrates a photovoltaic device comprising the substrate of FIG. 11 and in which electrical contacts are provided to said doped layers.

FIG. 13 illustrates identical half-cut IBC photovoltaic device provided by the separation in two halves, along said virtual axis, of the photovoltaic device of FIG. 12.

FIG. 14 illustrates a series of identical half-cut cells, as illustrated in FIG. 13, that are arranged with their flat side to the bottom of the box. When the two half-cut cells are positioned to present the same outer shape, as in a box, the columns of their conducting pads have all the same relative alternation of polarities.

FIG. 15 illustrates a photovoltaic string or module realized by arranging the identical half-cells as chosen from a stored ensemble of half-cells as illustrated in FIG. 6 and FIG. 14.

### DETAILED DESCRIPTION

The present invention will be described with respect to particular embodiments and with reference to certain drawings, but the invention is not limited thereto. The drawings described are only schematic and are non-limiting. In the drawings, the size of some of the elements may be exaggerated and not drawn on scale for illustrative purposes. The dimensions and the relative dimensions do not correspond to actual reductions to the practice of the invention.

It is to be noticed that the term “comprising” in the description and the claims should not be interpreted as being restricted to the means listed thereafter, i.e. it does not exclude other elements.

Reference throughout the specification to “an embodiment” means that a feature, structure or characteristic described in relation with the embodiment is included in at least one embodiment of the invention. Thus, appearances of the wording “in an embodiment” or, “in a variant”, in various places throughout the description are not necessarily all referring to the same embodiment, but several. Furthermore, the features, structures or characteristics may be combined in any suitable manner, as would be apparent to a skilled person from this disclosure, in one or more embodiments. Similarly, various features of the invention are sometimes grouped together in a single embodiment, figure or description, for the purpose of making the disclosure easier to read and improving the understanding of one or more of the various inventive aspects. Furthermore, while some embodiments described hereafter include some, but not other features included in other embodiments, combinations of features if different embodiments are meant to be within the scope of the invention, and from different embodiments. For example, any of the claimed embodiments can be used in any combination. It is also understood that the invention may be practiced without some of the numerous specific details set forth. In other instances, not all structures are shown in detail in order not to obscure an understanding of the description and/or the figures.

A horizontal plane herein is defined as a X-Y plane parallel to a face of the substrate. The wording “horizontal cross section means a cross section in a X-Y plane. The wording “vertical” or “on top” means here perpendicular to the substrate and in the direction of a Z-axis that is defined orthogonal to the substrates and in the direction of deposited doped structures. A vertical cross section is a cross section in a X-Z or Y-Z plane that comprises the vertical axis Z. A radial direction means a direction defined in a horizontal cross section. A lateral direction is defined in an X and/or Y direction in a horizontal plane. A width is defined as a width of a structure across a virtual line in a horizontal plane X-Y, said width is also defined as a diameter. Thicknesses are defined herein as thicknesses in the vertical Z-direction.

Herein, the term “collinear” means a configuration along a virtual line but this must not be perfectly onto a virtual line. For example, a column of contacts may be slightly off-line relative to a virtual line defined by another column of structures. “Facing columns” herein mean columns that are substantially aligned on the same virtual line.

As used herein the wording “substantial identical parts” mean parts that have the same layout of structures and electrical contacts but that may differ only according to slight differences in outer shape, outer dimensions or areas, such as differences provided by the cutting tool that separates a photovoltaic device in two nearly identical half-cells.

“Polarities” are defined herein as structures that configured for collecting positive electrical charge carriers and negative polarities for collecting negative electrical charge carriers, as known by the skilled person in the field of photovoltaic device.

“Electrical contacts” as defined herein are any type of electrical conducting layers or structures, typically deposited metallic structures that may be deposited by any technique on doped structures or layers.

Herein, “resized photovoltaic devices”, defined also as “half-cells” mean that they are obtained by separating a photovoltaic device in two portions that are preferably identical shaped portions.

A photovoltaic module defined herein is any assembly of a string of at least two photovoltaic half-cells, such as half-cells that are arranged on a support or frame. A module may comprise other structures such as protection layers and a full encapsulation and electrical contacts to connect the module to external electrical circuits and/or other modules.

The wordings “first portions and second portions” as used herein mean two parts defined in a photovoltaic device and which are separated by a virtual axis. The two portions provide two separate resized photovoltaic cells only when said “first portions and second portions” are separated by cutting the photovoltaic device, preferably in two substantially identical halves. Once separated in two halves, a photovoltaic device provides two separate photovoltaic half cells that may be provided as a product or assembled in a string to provide a module.

The wording “along said virtual axis X” means to realize an action performed along said virtual axis, such as a cutting or dicing action. The terms is considered broadly and may mean in close proximity, or following that axis comprising possible local deviations. For example, a cutting tool might not be very precise in cutting “along” a virtual axis.

The invention provides an interdigitated back contact (IBC) photovoltaic device 1 which comprises:
a silicon-based substrate 2 being of a p-type or n-type doping and having a first face defining a horizontal X-Y plane and a vertical direction Z orthogonal to said horizontal X-Y plane;
a patterned silicon layer 4 comprising a plurality of first-type structures 4′, being p-type or n-type doped structures, and a plurality of second-type structures 4″, being of the type opposite to said first-type, said first-type structures 4′ and second-type structures 4″ being of an alternating polarity type

The silicon-based substrate 2 that comprising on top of it said patterned silicon layer 4, is divided in a first portion 2a and a second portion 2b. The intersection of the two portions 2a, 2b define a virtual separation axis X. The separation axis X. comprising a device center C. The separation axis X is a virtual axis along which, or near to which, the full substrate, comprising said first and second structures 4′, 4″, is to be cut or split by any means in two halves.

Said first portion 2a comprises, arranged on said first-type structures 4′ and said second-type structures 4″, a plurality of electrical contacts 102a-102d to 120a-120d aligned as a first series 100 of parallel first columns 102, 104, 106, 108, 110, 112, 114, 116, 118, 120 (hereafter defined as 102-120) defining alternating positive and negative polarities, said first columns 102-120 being orthogonal to said virtual axis. The alternating polarities of the first columns 102-120 are to collect alternatively, in operation of the device 1, holes and electrons provided by the contacted underlying doped structures.

For reasons of clarity of the figures only some electrical contacts (102a, 102d, 120a, 120d, 202a, 202d, 220 a, 220d) are numbered for each portion 2a, 2b or half-sized device 10, 20 in the Figures.

The second portion 2b comprises, arranged on said second-type structures 4″ and said first-type doped structures 4′, a plurality of electrical contacts 202a-202d to 220a-220d aligned as a second series 200 of parallel second columns 202, 204, 206, 208, 210, 212, 214, 216, 218, 220 (hereafter defined as 202-220). The series of second columns define alternating negative and positive polarities and are, as said first columns orthogonal to said virtual axis. The alternating polarities of the first columns 102-120 are to collect alternatively, in operation of the device 1, holes and electrons provided by the contacted underlying doped structures.

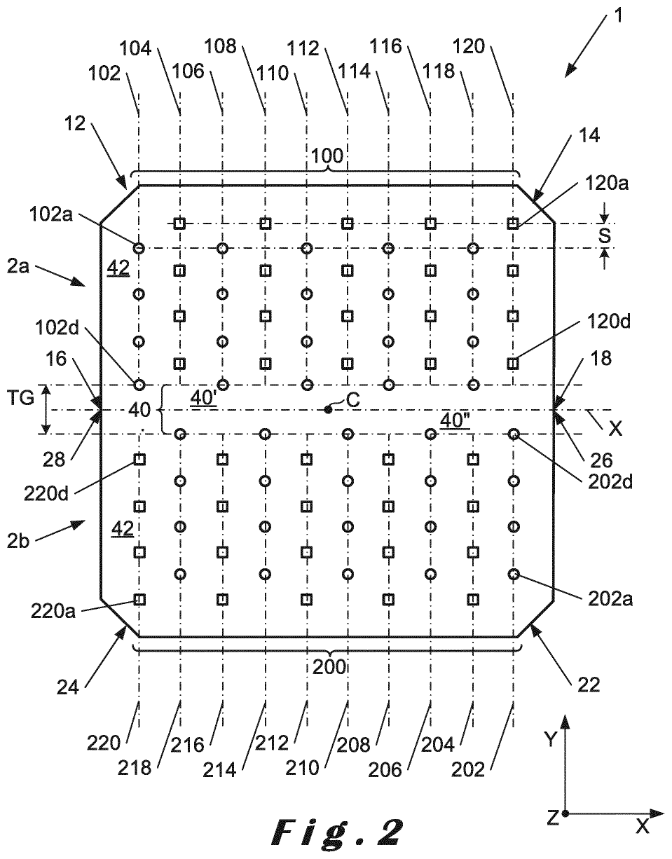

To the contrary of prior art devices, the geometry and arrangement of said parallel second columns 202-220 of second portion 2b is perfectly identical to the ones of said first portion (a) when virtually rotated, in said X-Y plane, by 180 degrees relative to said device center C when used as a virtual rotation center. This is obvious from FIG. 2.

Otherwise said, said second portion (2b) is perfectly identical, i.e. is a perfect image, to said first portion 2a when virtually rotated, in said X-Y plane, by 180 degrees relative to said device center C when used as a virtual rotation center.

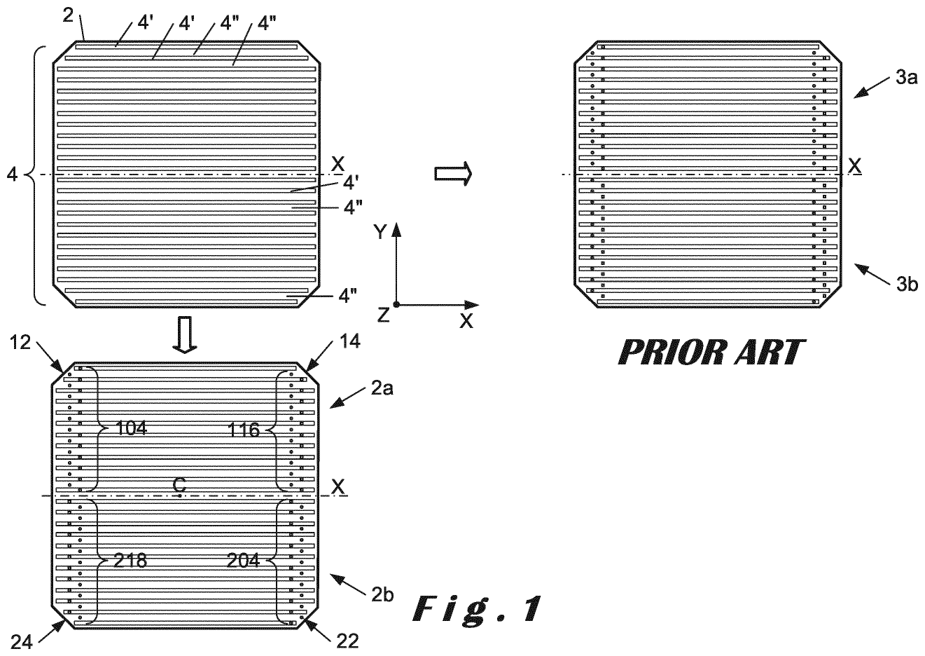

To the contrary of prior art devices illustrated in FIG. 1 (“Prior Art”) one cannot achieve this: if the lower part of a prior art device would be virtually rotated by 180° around the device center C as virtual rotation center, it is obvious that the lower and upper half-portions of prior art devices are not identical,

As illustrated in FIG. 1 the layout of the electrical contacts of the device 1 of the invention is totally different than the one of prior art devices wherein the two portions 3a, 3b comprise columns that extend over the whole length orthogonal to a virtual central axis X of a photovoltaic device, each column comprising identical type of electrical contacts.

In a variant two adjacent columns could have the same polarity side by side, for example in the center part of the photovoltaic device 1.

The first portion 2a comprises, to its side away from said virtual axis X, at least one corner 12, 14 that is not a rectangular corner. Such corner may have any shape.

The second portion 2b comprises, to its side away from said virtual axis X, at least one corner 22, 24 that is not a rectangular corner. Such corner may have any shape.

The first and second portions 2a, 2b comprise, to the side of said X-axis flat sides 2a′, 2b′ defined as the sides that comprise each two substantially identical shaped corners, preferably rectangular corners 16, 18, 26, 28. The precise shape of the rectangular corners 16, 18, 26, 28 may depend on the mechanical or laser cutting or the sawing or breaking tooling, so they may be slightly different than an exact rectangular corner.

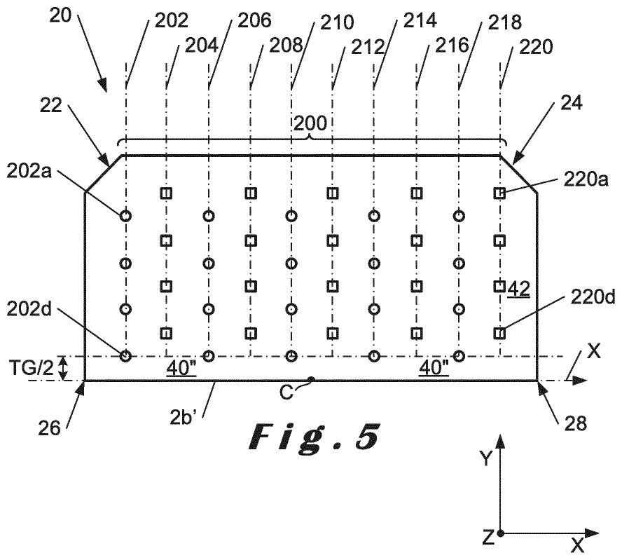

In FIGS. 3-5 only 4 electrical contacts are illustrated per columns, for reasons of clarity of the Figures. In practice the number of electrical contacts in a column of a half-cell 10, 20 may be more than 10, more than 20, even more than 50. A typical number of electrical contacts in a column are between 30 and 40.

Between the silicon structures 4a, 4b, and the electrical contacts an additional structured, electrically conducting charge collection layer can be applied. This conducting layer can be made of any electrically conducting material and is used to efficiently transfer electrical charges from the silicon structures to the electrical contacts. For example, it may be a transparent conductive oxide (TCO) layer) and a metallic stack layer that may comprise copper (Cu).

The electrical contacts can be of any shape and size and are usually designed to establish a reliable electrical contact between the silicon substructure and conductors used to interconnect neighboring solar cells.

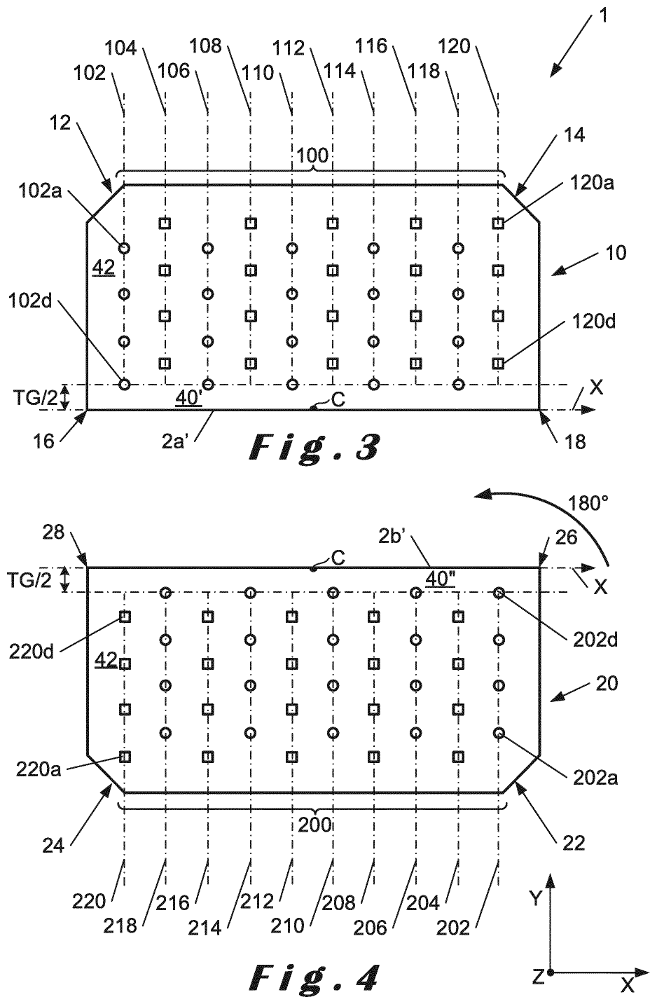

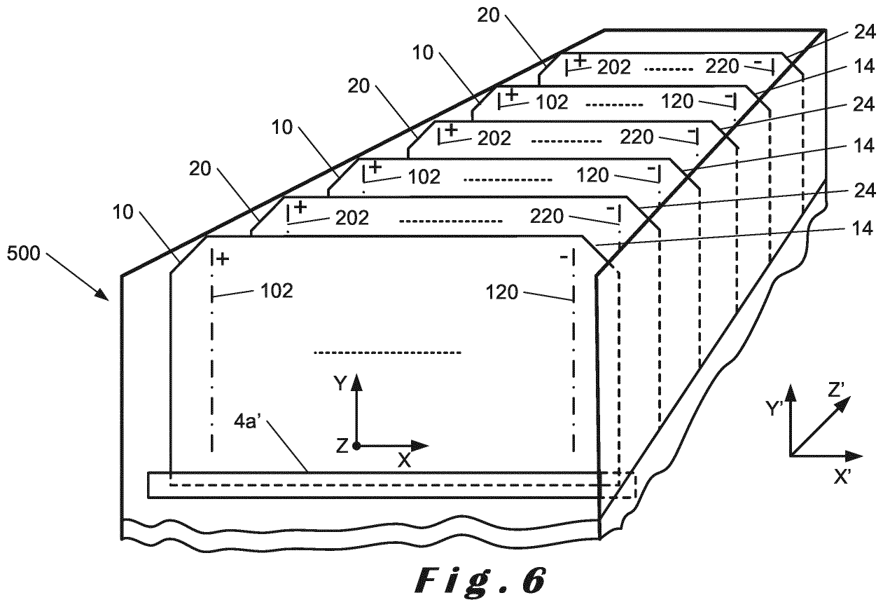

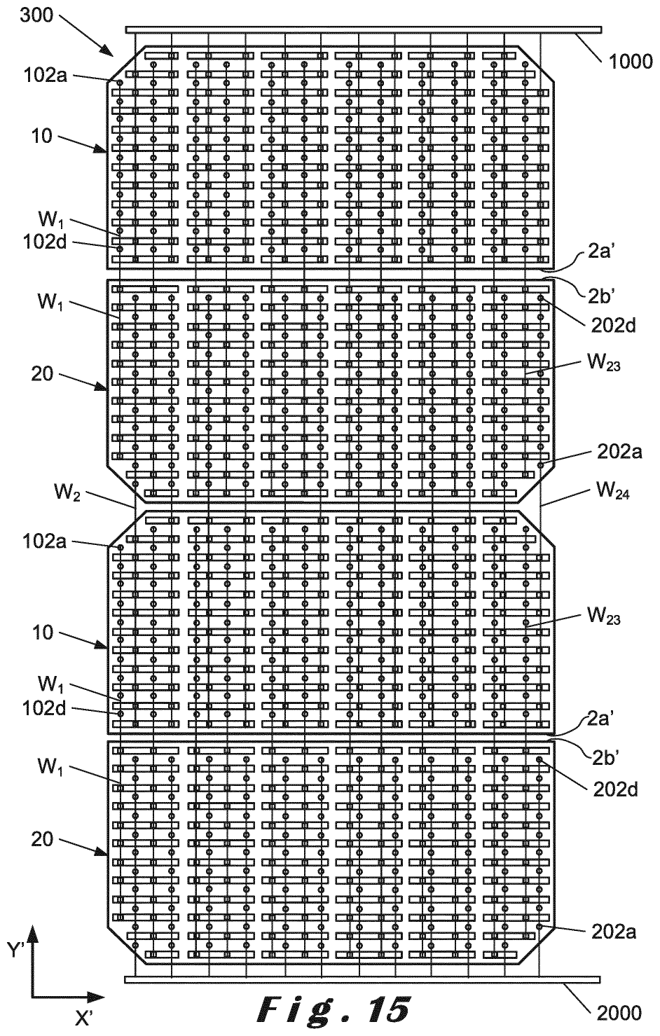

In the photovoltaic device 1 and in the half-cells 10, 20 as arranged in modules or strings 300, each of the electrical contacts 102a-d-120 a-d of said first columns 102-120 have, in the length Y orthogonal to said virtual axis X, a polarity opposite to the polarity of the electrical contacts 202a-d-220 a-d of a facing second column 202-220. For example, in FIG. 2 the electrical contacts arranged along a column 102 face, and are in line, with opposite polarities of the contacts of the facing column 220. The first column 102 of the first portion 2a is identical to the column 202 of the second portion 2a, when viewed with their flat sides 2a′, 2b′ placed to the same support (FIG. 14 for example), so that, when separated, and turned by 180° the second portion 2b, once cut being half-cell 20, is identical with the first portion 2a, as illustrated in FIGS. 3 and 4. Otherwise said, a turned half cell 20 corresponds to the second portion 2b, and positioned with the same orientation than the half-cell 10 provided by the first portion 2a, it is identical to it. This is illustrated in FIGS. 6 and 14 wherein the plurality of half-cells 10, 20 are all arranged in a storage box or cartridge with all their flat sides 2a′, 2b′ to the same side.

The design of the photovoltaic device 1 and so the resized cells 10, 20 of the invention, allows to provide two identical types of solar cell pieces. This has the advantage that the solar cell pieces can be sorted and stocked like standard full-sized cells without separating two types of polarity arrangements as it would be necessary for prior art designed cells.

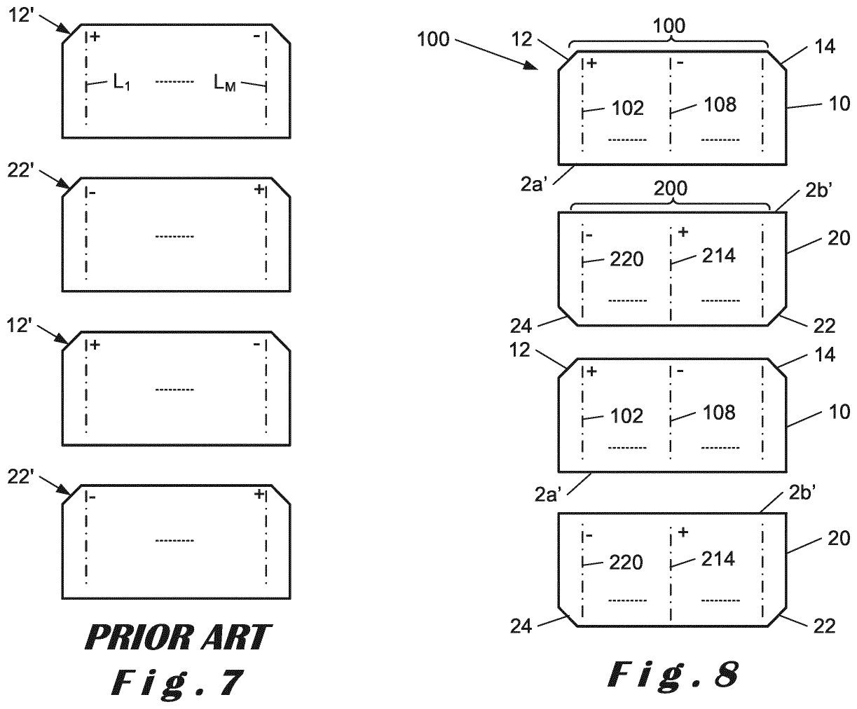

By that, one also does not need to know the specific order of the polarities of the arrays 100, 200 of columns of electrical contacts between two successive half-cells, to the contrary of prior art half-cells. As illustrated in FIGS. 8 and 15 it is sufficient to arrange the half-sides 10, 20 in a string or module 300 so that their flat sides 2a′, 2b′ face each other as illustrated in FIG. 8. This is totally different to arrangements of prior art, illustrated in FIG. 7, which present a risk if a wrong choice of half-cells 10, 20 is made, which may occur by making a human error, or when an automatic system misses or selects wrongly the correct half-cell type. Making a single error in the choice of prior-art half-cells may lead to the electrical failure or even destruction of a complete module 300.

The resized photovoltaic devices 10, 20 comprise, to their sides away from said virtual axis X, at least one corner 12, 14, 22, 24, that is not a rectangular corner. The shape of this corner 22, 24 may be any shape. This allows to identify without error the orientation of the half-cells before assembling them in a module. Indeed, to the contrary of prior art half-cells, it is sufficient to align the flats sides 4a′, 4b′ in a module so that they face each other as illustrated in FIGS. 8 and 15.

The difference between prior art half-cells and the ones provided by the invention is illustrated in FIG. 1. The invention provides photovoltaic modules 300 that are easier to fabricate and also less expensive. Furthermore, by the design of the photovoltaic device 1 and the resized cells 10, 20, a risk of electrical damage is totally removed as there cannot be any orientation error of the half-cells 10, 20 on the layout of a module 300. The reason is that they rely on the realization and providing of identical half-cells to the contrary of prior art modules based on half photovoltaic cells that rely on different half-cells. The problem related with prior art cells is that they are different, so they have to be stored in a such a way which requires to identify them individually, as they have all to be aligned in a sequence according to their identical shape. This difference is further illustrated in FIG. 7 (alignment in prior art modules) and FIG. 8 (alignment in modules 300 of the invention).

In an embodiment, the number N of first columns 102-120 and second columns 202-220 are equal and/or is a pair number. The number N may be more than 10, possibly more than 20, even more than 50 for a 6 inch wafer. Typical values of the number N is about 18 for a 6-inch wafer!

In an embodiment, the photovoltaic device comprises 4 corners 12, 14, 22, 24 that are non-rectangular corners.

In an embodiment, at least 2 of the 4 corners 12, 14, 22, 24 are different shaped corners.

In embodiments the number of electrical contacts in a column of a half-cell 10 may be different than the number of electrical contacts in a column of a second adjacent half-cell 10. Also, in a variant, the number of lines or islands of doped structures may be different for two adjacent half cells 10, 20.

In a preferred embodiment, said electrical contacts 102a-d to 120 a-d, 202a-d to 220 a-d are realized in apertures realized in a deposited layer 42 arranged onto said first type 4′ and second type 4″ of said patterned silicon layer 4.

In an embodiment, said deposited layer 42 is a fully insulating layer arranged onto said patterned silicon layer.

Between the silicon structures 4a, 4b, and the electrical contacts 102a-d to 120 a-d, 202a-d to 220 a-d an additional structured and electrically conducting charge collection layer is preferably applied. This conducting layer can be made of any electrically conducting material and is used to efficiently transfer electrical charges from the silicon structures to the electrical contacts. The additional charge collecting layer is connecting only one polarity type structures and it is also between the doped silicon structures and the contact structures.

In an embodiment, said first 2a and said second portions 2b are separated by a gap area 40, extending in the direction of said virtual X-axis and having a width TG defined in the Y-axis orthogonal to said virtual X-axis. Providing a dedicated gap which is wider than the separation between the electrical contacts in the Y direction. This may make the dicing or cutting operation between the two portions of the device 1 easier and requiring less precision.

The wafer may be cut by a cutting tool or machine but the photovoltaic device 1 may also be separated in two parts 10, 20 by a scratch-and break method, and/or or by using a laser. In such a case a gap area 40 that is wider than the separation between the electrical contacts in the Y direction, may allow to provide less requirement for the positioning precision of the cutting, scratching and/or breaking tool or machine.

In an example of execution of the invention, a protection layer or protection coating may be provided onto said gap area 40. This may be useful to protect the portions 2a, 2b of the device 10 during the separation operations.

In an embodiment, the width TG of the gap area 40, comprising to the sides of the axis X two portions 40′, 40″, is greater than the separation S, in the Y direction, of said electrical contacts 102a-d to 120a-d, 202a-d to 220a-d. The widths of the two portions 40′, 40″ may each be TG/2.

The invention is also achieved by resized photovoltaic devices 10, 20 being said first portion 2a or said second portion 2b as preferably obtained by the physical separation in two halves, along said virtual axis X, of the photovoltaic device as described.

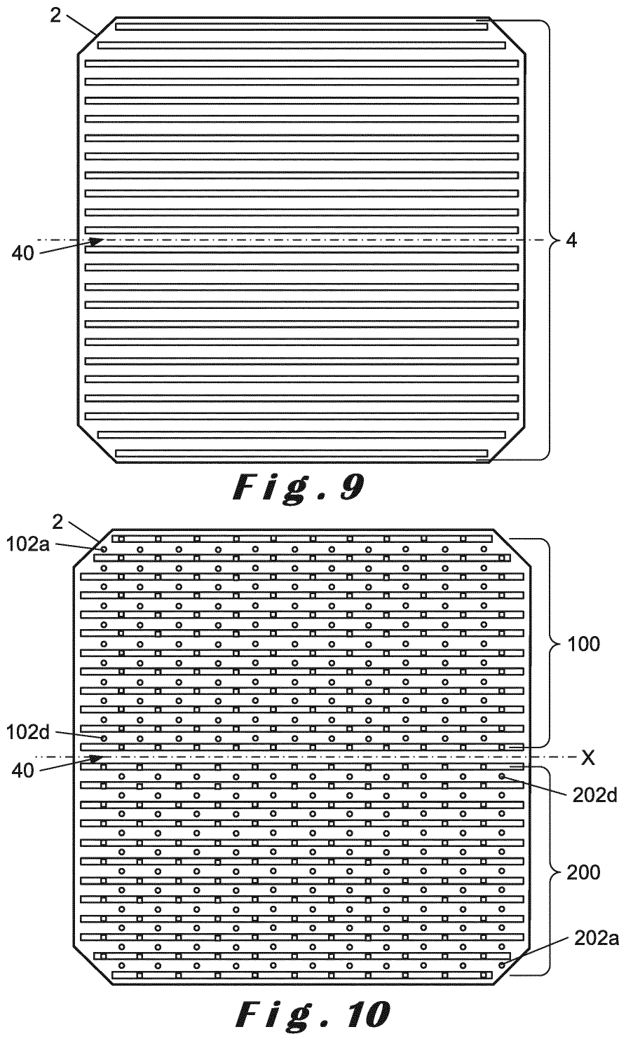

FIG. 9 illustrates a typical realized substrate 2 and FIG. 10 a photovoltaic device 1 based on a structured layer 4 comprising linear shaped doped structures 4′ that cross substantially the width of a substrate and that are surrounded by doped areas 4″ of the opposite doping type.

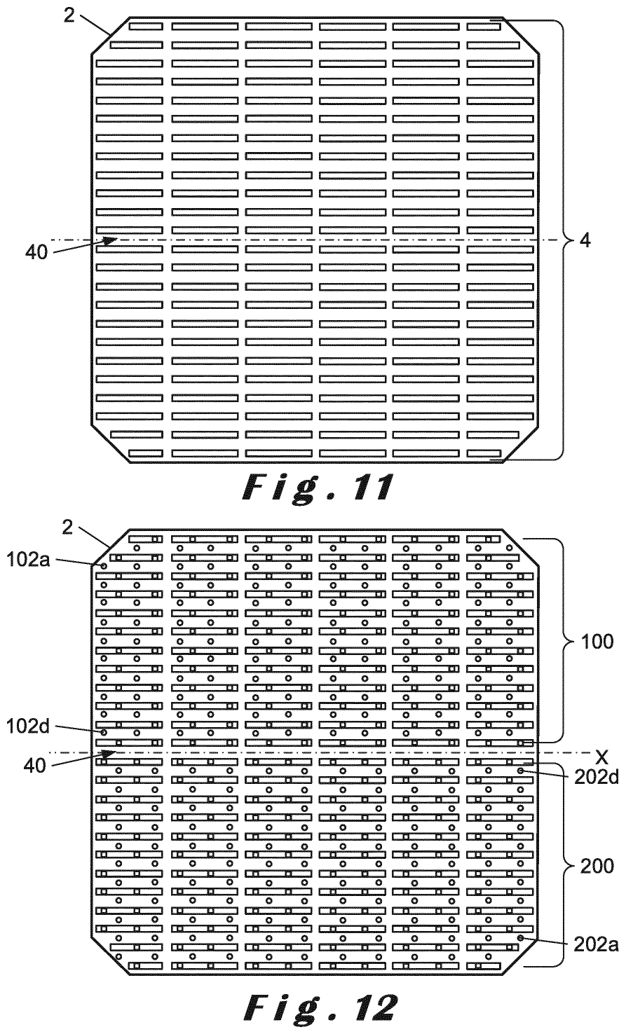

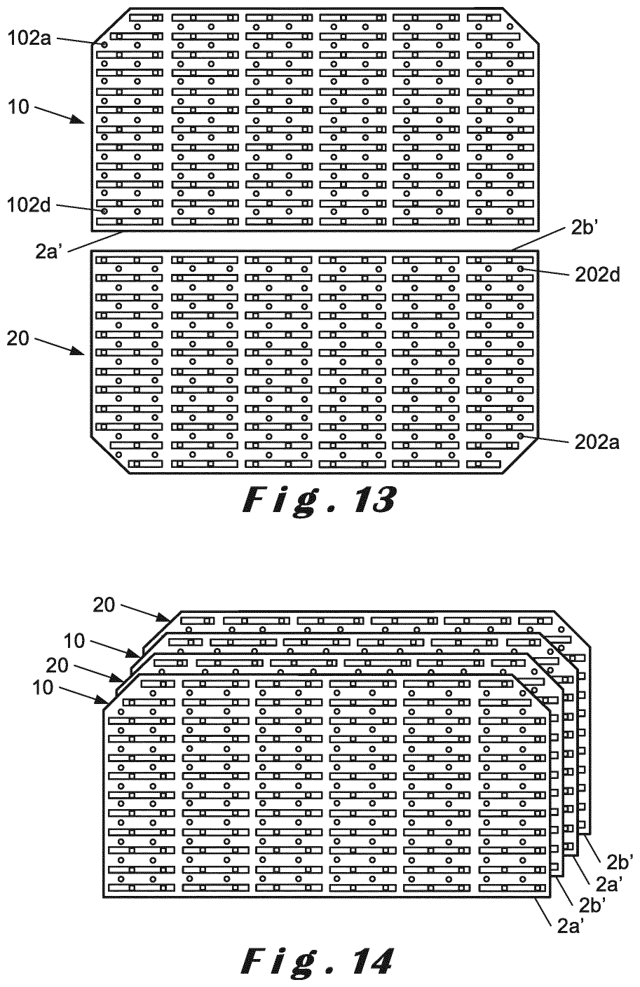

FIGS. 11, 12 illustrates a typical realized substrate 2 and photovoltaic device 1 based on substrate 2 comprising a structured layer 4 composed of a matrix of elongated doped structures 4′ that are surrounded by doped areas 4″ of the opposite doping type. FIG. 13 illustrates two resized half-cells 10, 20 as provided by the separation in two halves of the photovoltaic device 1 of FIG. 12.

In variants, the two portions 10, 20 may have a different shape or area. For example, the virtual axis X, which is the separation axis, must not be perfectly centred in the mid-line the separation. Once separated as two resized photovoltaic devices 10, 20, the distance from the lowest virtual line of contacts to the flat sides 2a′, 2b′ may be different, i.e. the remaining gap areas 40′ and 40″ may have a different area and/or width in the Y direction.

In an embodiment, the photovoltaic module 300 comprises a plurality of adjacent resized photovoltaic devices 10, 20 that are arranged so that at least one of said first columns 102-120 of each first resized photovoltaic device 10 is not facing second column 102-120 of an adjacent second resized photovoltaic device 20.

The invention is also achieved by a photovoltaic module 300 comprising a string of adjacent resized photovoltaic devices 10, 20, as illustrated in FIG. 15. The photovoltaic module 300 defines a module plane X′-Y′, X′ defining the direction of the width of a module 300.

In a preferred embodiment, the module 30 is arranged so that all of said first columns 102-120 of each first resized photovoltaic device 10 is on a virtual line defined by a second column 102-120 of an adjacent second resized photovoltaic device 20 and so that facing columns 100, 200 of adjacent half-cut cells 10, 20 have opposite polarities.

In a variant, adjacent resized photovoltaic devices 10, 20 may be arranged so that at least 80%, preferably at least 90% of said first column 102-120 of each first resized photovoltaic device 10 is on a virtual line defined by a second column 102-120 of an adjacent second resized photovoltaic device 20 and so that facing columns 100, 200 of adjacent half-cut cells 10, 20 have opposite polarities. This may occur either by the layout of the electrical contact columns 100, 200 of the resized devices 10, 20 or in an arrangement of the module 300 wherein adjacent resized devices 10, 20 are arranged with a lateral displacement in the width direction X′

In a preferred embodiment, a module 300 comprises conductors W1-W24 that are realized between the electrical contacts once the half cells 10, 20 are arranged on a frame of a module 300 as described further. FIG. 15 illustrates a module 300 comprising 24 straight contact layers or wires W1-W24 but other numbers may be possible for example 48 contact layers. The module 300 comprises also interconnecting conductors 1000, 2000 as illustrated in FIG. 15.

In an embodiment wherein the first portion and the second have each a chamfered corner, on arrangement in said module 300, the half cells of the invention will have chamfered corners alternating once up once down, i.e. relative to the axis Y′ as illustrated in the example of FIG. 15.

The invention is also achieved by a method for manufacturing of a photovoltaic device 1 The method comprises the steps of:
providing a patterned silicon layer 4, comprising a plurality of first-type structures 4′, being p-type or n-type doped structures, and a plurality of second-type structures 4″, being of the type opposite to said first-type and defining two identical portions 2a, 2b being a first portion 2a and a second portion 2b separated by a virtual separation axis X that includes a device center C, said first 2a and second 2b portion comprising, to their side away from said virtual axis X, at least one corner 12, 14 that is not a rectangular corner;
realizing in said first portion 2a, alternatively on said first-type structures 4′ and said second-type structures 4″, a plurality of electrical contacts 102a-d-120a-d, to provide a first series 100 of parallel first columns 102-120 of electrical contacts that contact alternatively said first 4′ and said second 4″ structures and provide columns of alternating positive and negative polarities in the direction of said virtual separation axis X;
realizing in said second portion 2b, on said first type structures 4′ and said second-type structures 4″, a plurality of electrical contacts 202a-d-220 a-d, to provide a second series 200 of parallel second columns 202-220 of electrical contacts that contact alternatively said first 4′ and said second 4″ structures and provide columns having alternating positive and negative polarities in the direction of said virtual separation axis X.

The invention is also achieved by a method to realize resized photovoltaic cells 10, 20 and comprises the steps of:
realizing a photovoltaic device 1 as described;
separating, along said virtual axis X, the photovoltaic device 1 in two substantially identical resized photovoltaic devices 10, 20.

In an embodiment, the method of realizing and providing resized photovoltaic devices 10, 20 and modules 300 comprises the storage of a plurality of resized photovoltaic devices 10, 20 in a storage box 500. Such storage box may be part of an automatic handling systems.

The invention is also realized by a method for manufacturing a photovoltaic module or string of resized photovoltaic devices 10, 20, and comprises the step of assembling the resized photovoltaic devices 10, 20 in a way that columns 100, 200 of electrical contacts 102-120, 202-220 are facing each other in a way that columns 100, 200 that are aligned along virtual lines, represented by said columns 100, 200, have opposite polarities in an alternating way.

In an embodiment, the electrical connection between resized photovoltaic devices 10, 20 is performed by connecting columns of a first polarity of a resized photovoltaic device 10 with columns of a second polarity, opposite to the first polarity, of an adjoining resized photovoltaic device 20, and by that realizing a series interconnection of the adjoining devices 10, 20.

1. An interdigitated back contact photovoltaic device comprising:
a silicon-based substrate being of a p-type or n-type doping and having a first face defining a horizontal X-Y plane and a vertical direction Z orthogonal to said horizontal X-Y plane;
a patterned silicon layer comprising a plurality of first-type structures, being p-type or n-type doped structures, and a plurality of second-type structures, being of the type opposite to said first-type, said first-type structures and second-type structures being of an alternating polarity type,
wherein
said silicon-based substrate, comprising said patterned silicon layer, is divided in a first portion and a second portion, the intersection of the two portions defining a virtual separation axis comprising a device center,
said first portion comprises, arranged on said first-type structures and second type structures, a plurality of electrical contacts aligned as a first series of parallel first columns defining alternating positive and negative polarities, said first columns being orthogonal to said virtual axis,
said first portion comprises, to a side of the first portion away from said virtual axis, at least one corner that is not a rectangular corner,
said second portion comprises, arranged on said second-type structures and said first-type structures, a plurality of electrical contacts aligned as a second series of parallel second columns defining alternating negative and positive polarities, said second columns being orthogonal to said virtual axis,
said second portion being identical to said first portion when virtually rotated, in said X-Y plane, by 180 degrees relative to said device center as virtual rotation center,
each of the electrical contacts of said first columns have, in the length orthogonal to said virtual axis, a polarity opposite to the polarity of the electrical contacts of a collinear second column,
said second portion comprises, to a side of the second portion away from said virtual axis, at least one corner that is not a rectangular corner.

2. The photovoltaic device according to claim 1 wherein the number N of first columns and second columns are equal and/or is a pair number.

3. The photovoltaic device according to claim 1, wherein at least a part of said first columns and at least a part of said second columns comprises an electrical connection layer connecting the electrical contacts.

4. The photovoltaic device according to claim 1, wherein said electrical contacts are realized in apertures realized in a deposited layer comprising a plurality of isolating portions arranged onto said first type and second type of said patterned silicon layer.

5. The photovoltaic device according to claim 4, wherein said deposited layer is a fully insulating layer arranged onto said patterned silicon layer.

6. The photovoltaic device according to claim 1, wherein said first and said second portions are separated by a gap area, extending in the direction of said virtual X-axis and having a width defined in the Y-axis orthogonal to said virtual X-axis.

7. A resized photovoltaic device being said first portion or said second portion as obtained by a physical separation, along said virtual axis X, in substantially two halves, of the photovoltaic device according to claim 1.

8. A photovoltaic module comprising a plurality of adjacent resized photovoltaic devices according to claim 7 and which are arranged so that at least 80% of said first or second column of each first resized photovoltaic device is on a virtual line defined by a second or first column of an adjacent second resized photovoltaic device and so that facing columns of adjacent resized photovoltaic device have opposite polarities.

9. The photovoltaic module according to claim 8 comprising a plurality of adjacent resized photovoltaic devices that are arranged so that at least one of said first columns of each first resized photovoltaic device is not facing a second column of an adjacent second resized photovoltaic device.

10. Method for manufacturing a photovoltaic device according to claim 1, comprising the steps of:
providing a patterned silicon layer, comprising a plurality of first-type structures, being p-type or n-type doped structures, and a plurality of second-type structures, being of the type opposite to said first-type and defining two identical portions being a first portion and a second portion separated by a virtual separation axis that includes a device center, said first and second portion comprising, to their side away from said virtual axis, at least one corner that is not a rectangular corner;
realizing in said first portion, on said first-type structures and said second-type structures, a plurality of electrical contacts, arranged as a first series of parallel first columns of alternating positive and negative polarities in the direction of said virtual separation axis X;
realizing in said second portion, on said second-type structures and said first-type structures, a plurality of electrical contacts, arranged as a second series of parallel second columns having alternating positive and negative polarities in the direction of said virtual separation axis X;
wherein:
each of the electrical contacts of said first columns in said first portion a have, in the length orthogonal to said virtual axis, a polarity opposite to the polarity of the electrical contacts of a facing second column in said second portion.

11. A method to realize resized photovoltaic cells comprising the steps of:
manufacturing the photovoltaic device of claim 1, by:
providing a patterned silicon layer, comprising a plurality of first-type structures, being p-type or n-type doped structures, and a plurality of second-type structures, being of the type opposite to said first-type and defining two identical portions being a first portion and a second portion separated by a virtual separation axis that includes a device center, said first and second portion comprising, to their side away from said virtual axis, at least one corner that is not a rectangular corner;
realizing in said first portion, on said first-type structures and said second-type structures, a plurality of electrical contacts, arranged as a first series of parallel first columns of alternating positive and negative polarities in the direction of said virtual separation axis X; and
realizing in said second portion, on said second-type structures and said first-type structures, a plurality of electrical contacts, arranged as a second series of parallel second columns having alternating positive and negative polarities in the direction of said virtual separation axis X;
wherein each of the electrical contacts of said first columns in said first portion have, in the length orthogonal to said virtual axis, a polarity opposite to the polarity of the electrical contacts of a facing second column in said second portion; and
separating the photovoltaic device along the virtual axis X in two substantially identical resized photovoltaic devices.

12. The method according to claim 11, further comprising storing a plurality of the resized photovoltaic devices in a storage box.

13. Method for manufacturing a photovoltaic module according to claim 8, comprising the step of assembling photovoltaic devices in a way that columns of contacts are facing each other in a way that columns that are aligned in virtual lines represented by columns do have opposite polarities in an alternating way.

14. Method for manufacturing a photovoltaic module according to claim 8, by connecting columns of a first polarity of a resized photovoltaic device with columns of a second polarity, opposite to the first polarity, of an adjoining resized photovoltaic device and by that realizing an electrical series interconnection of the adjoining resized photovoltaic cells.

15. The photovoltaic device according to claim 2, wherein at least a part of said first columns and at least a part of said second columns comprises an electrical connection layer connecting the electrical contacts.

16. The photovoltaic device according to claim 15, wherein said electrical contacts are realized in apertures realized in a deposited layer comprising a plurality of isolating portions arranged onto said first type and second type of said patterned silicon layer.

17. The photovoltaic device according to claim 16, wherein said deposited layer is a fully insulating layer arranged onto said patterned silicon layer.

18. The photovoltaic device according to claim 17, wherein said first and said second portions are separated by a gap area, extending in the direction of said virtual X-axis and having a width defined in the Y-axis orthogonal to said virtual X-axis.
